(19) United States
(12) Patent Application Publication
(10) Pub. No.: US 2026/0308744 A1
(43) Pub. Date: Oct. 8, 2026

(54) DEPOSITION MASK, METHOD OF FABRICATING THE SAME, METHOD OF MANUFACTURING DISPLAY DEVICE USING THE SAME AND ELECTRONIC DEVICE INCLUDING THE DISPLAY DEVICE

(71) Applicant: Samsung Display Co., LTD., Yongin-si (KR)

(72) Inventor: Sung Woon KIM, Yongin-si (KR)

(21) Appl. No.: 19/555,118

(22) Filed: Mar. 3, 2026

(30) Foreign Application Priority Data
Apr. 4, 2025 (KR) 10-2025-0044299

(51) Int. Cl. C23C 14/04; H10K 59/12; H10K 71/16

(52) U.S. Cl. CPC C23C 14/042; H10K 59/1201; H10K 71/166

(57) ABSTRACT

In a method of fabricating a deposition mask, a first photoresist pattern including first holes and a second photoresist pattern including second holes are formed on a first surface and a second surface of a mask body, respectively. The first surface and the second surface oppose each other. The mask body is etched to define first recesses at an upper portion of the mask body through the first holes and define second recesses connected to each of the first recesses at a lower portion of the mask body through the second holes. Each of the second holes has a width smaller than a width of each of the first holes, and each of the second recesses has a width larger than a width of each of the first recesses.

This application claims priority to Korean Patent Application No. 10-2025-0044299, filed on Apr. 4, 2025, and all the benefits accruing therefrom under 35 U.S.C. §119, the content of which in its entirety is herein incorporated by reference.

### BACKGROUND

### 1. Field

Embodiments of the disclosure relate to a deposition mask, a method of fabricating the same, a method of manufacturing a display device using the same, and an electronic device including the display device. More particularly, embodiments of the disclosure relate to a deposition mask including a deposition hole, a method of fabricating the same, a method of manufacturing a display device using the same, and an electronic device including the display device.

### 2. Description of the Related Art

In a display device such as an organic light-emitting diode (“OLED”) display device and a liquid crystal display (“LCD”) device, a display substrate including thin film transistors (“TFTs”) and various wirings may be provided, and a display structure including electrodes and emission layers may be formed on the display substrate.

For example, the OLED display device may include a light-emitting element including an organic emission layer. The organic emission layer may be patterned for each color or each pixel using a deposition mask. As a resolution of the OLED display device increases, fine patterning for forming the deposition mask may be desired.

### SUMMARY

A feature of the disclosure provides a deposition mask providing improved deposition reliability and deposition efficiency.

A feature of the disclosure provides a method of fabricating a deposition mask providing improved deposition reliability and deposition efficiency.

A feature of the disclosure provides a method of manufacturing a display device using the deposition mask.

A feature of the disclosure provides an electronic device including the display device.

In an embodiment of a method of fabricating a deposition mask, a first photoresist pattern including first holes and a second photoresist pattern including second holes may be formed on a first surface and a second surface of a mask body, respectively. The first surface and the second surface oppose each other. The mask body may be etched to define first recesses at an upper portion of the mask body through the first holes and define second recesses connected to each of the first recesses at a lower portion of the mask body through the second holes. Each of the second holes may have a width smaller than a width of each of the first holes, and each of the second recesses has a width larger than a width of each of the first recesses.

In an embodiment, the first recesses may serve as deposition source outlets and the second recesses may serve as deposition source inlets.

In an embodiment, a pitch of the second holes may be smaller than a pitch of the first holes.

In an embodiment, the number of the second holes may be greater than the number of the first holes.

In an embodiment, in etching the mask body to define the first recesses and the second recesses, a first etching may be performed to define the first recesses at the upper portion of the mask body through the first holes and define second preliminary recesses at the lower portion of the mask body through the second holes. A second etching may be performed to expand the second preliminary recesses to define the second recesses connected to each of the first recesses.

In an embodiment, in the defining the second recesses, neighboring (adjacent) second preliminary recesses may be merged to define the second recess connected to one of the first recess.

In an embodiment, a width of each of the second preliminary recesses may be smaller than the width of each of the first recesses.

In an embodiment, in the defining the second recesses, three or more neighboring (adjacent) second preliminary recesses may be merged to define the second recess.

In an embodiment, before performing the second etching, a barrier layer filling the first recesses may be defined in the first photoresist pattern.

In an embodiment, after performing the second etching to define the second recesses, the barrier layer, the first photoresist pattern and the second photoresist pattern may be removed to define a deposition hole through which the first recess and the second recess are connected.

In an embodiment, a first hole group may be defined by a plurality of neighboring first holes among the first holes, and a second hole group corresponding to the first hole group and including a plurality of neighboring second holes among the second holes is defined.

In an embodiment, an interval between the second holes included in the second hole group is smaller than an interval between the first holes included in the first hole group.

In an embodiment, a plurality of first hole groups are defined in the first surface, and a plurality of second hole groups are defined in the second surface. An interval between the first hole groups may be smaller than an interval between the second hole groups.

In an embodiment, in the defining the second recesses, facing side portions of the second recesses defined from the second holes included in the second hole group may be merged.

In an embodiment, in a method of manufacturing a display device, a back-plane structure including a base substrate, a transistor on the base substrate and a pixel electrode electrically connected to the transistor may be prepared. The back-plane structure may be aligned over the deposition mask fabricated as described above such that the pixel electrode may face the first recess of the deposition mask. An emission layer may be formed on the pixel electrode by injecting an emission material from the second recess of the deposition mask to the first recess. A counter electrode may be formed on the emission layer.

In an embodiment, in forming the emission layer on the pixel electrode, a first emission layer may be formed by injecting a first emission material that emits a first color through the deposition mask. A second emission layer may be formed by shifting the deposition mask and injecting a second emission material that emits a second color. A third emission layer may be formed by shifting the deposition mask and injecting a third emission material that emits a third color.

In an embodiment, an electronic device may include the display device manufactured as described above, a memory, and a processor executing data included in the memory to control an operation of the display device.

In an embodiment, a deposition mask may include a mask body, and deposition holes penetrating the mask body. Each of the deposition holes may include a first recess and a second recess connected to the first recess. The second recess may have a width greater than a width of the first recess. Facing side portions of the second recesses included in neighboring (adjacent) deposition holes may be merged with each other.

In an embodiment, a deposition hole group may be defined by the second recesses merged with each other through the facing side portions and the first recesses connected to each of the second recesses.

In an embodiment, the deposition hole group may include a merged portion at which the second recesses are merged. A height of the merged portion may be less than a maximum height of each of the second recesses.

In an embodiment of the disclosure, a hole width or a hole interval of a photoresist pattern formed on a deposition source injection surface of a mask body of a deposition mask may be relatively reduced. Thereafter, a size of a recess may be gradually increased by a first etching and a second etching through the deposition source injection surface to define a high-resolution deposition hole with relatively high reliability.

High-resolution fine patterning of an emission layer of a display device may be implemented with relatively high reliability using the deposition mask.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a schematic exploded perspective view illustrating embodiments of a deposition mask assembly.

FIGS. 2-7 are schematic cross-sectional views illustrating embodiments of a method of fabricating a deposition mask.

FIGS. 8 and 9 are schematic cross-sectional views illustrating a method of fabricating a deposition mask according to a comparative example.

FIGS. 10-14 are schematic cross-sectional views illustrating embodiments of a method of fabricating a deposition mask.

FIGS. 15-19 are schematic cross-sectional views illustrating embodiments of a method of fabricating a deposition mask.

FIGS. 20-25 are schematic diagrams illustrating embodiments of a method of manufacturing a display device.

FIG. 26 is an exploded perspective view illustrating embodiments of an electronic device.

FIG. 27 is a block diagram of an embodiment of an electronic device.

FIG. 28 is a schematic diagram of embodiments of electronic devices.

### DETAILED DESCRIPTION

Hereinafter, embodiments of the disclosure will be described in more detail with reference to the attached drawings. The same reference numerals may be used for indicating the same elements in the drawings, and repeated descriptions of the same elements may be omitted. Embodiments disclosed in the attached drawings are exemplary, and is to be understood to include all modifications, equivalents and substitutes included in the spirit and technical scope of the disclosure.

The terms "on", "connected", "coupled," etc., used herein refers to a direct placement/connection/combination, and also refers to a case where another element is interposed two different elements.

The terms such as "first", "second", "below", "lower", "upper", "above," etc., are used in a relative sense to distinguish different elements or positions, and do not specify an absolute position or an absolute order.

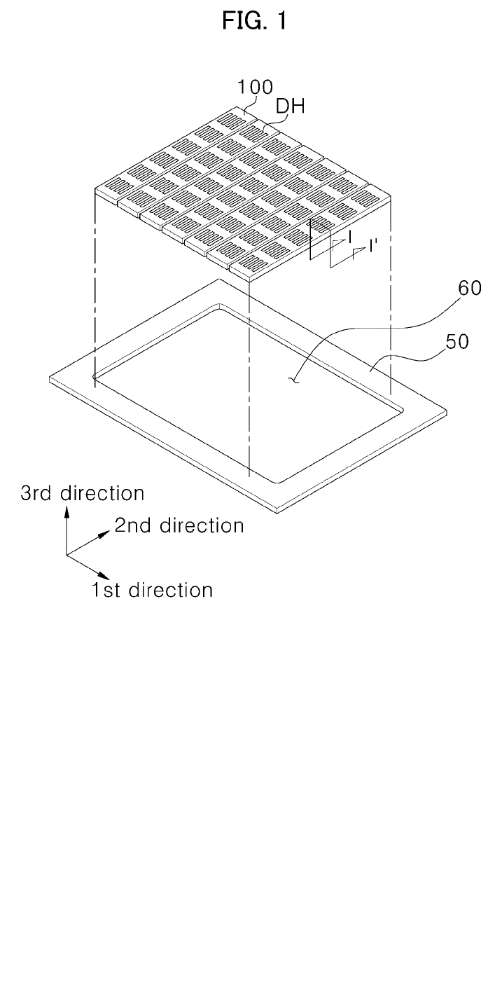

FIG. 1 is a schematic exploded perspective view illustrating embodiments of a deposition mask assembly.

Referring to FIG. 1, a deposition mask assembly may include a deposition mask 100 and a frame 50 for fixing the deposition mask 100. In FIG. 1, two directions parallel to a surface (a top surface or a bottom surface) of the deposition mask 100 or a surface (a top surface or a bottom surface) of the frame 50, and perpendicular to each other are referred to as a first direction and a second direction. In an embodiment, the first direction may be a short side direction of the deposition mask 100, and the second direction may be a long side direction of the deposition mask 100, for example. The third direction may refer to a direction perpendicular to the first and second directions. In an embodiment, the third direction may be a thickness direction of the deposition mask 100, for example.

The definitions of the directions described above may be equally applied to the accompanying drawings.

In an embodiment, the first direction and the second direction may refer to two directions parallel to a display surface of a display device or an electronic device, and perpendicular each other. In an embodiment, the first direction may correspond to an X-direction (a width direction or a row direction) of the display device, and the second direction may correspond to a Y-direction (a length direction or a column direction) of the display device, for example. The third direction may correspond to a Z-direction (a thickness direction) of the display device or the electronic device.

The deposition mask 100 may define a deposition hole DH which may penetrate the deposition mask 100, and through which a deposition source may pass. The deposition mask 100 may include a plurality of deposition holes DH. In an embodiment, a plurality of deposition holes DH may be formed in the first direction to define a deposition hole row, for example. A plurality of deposition hole rows may be repeatedly formed along the second direction.

Although the deposition hole DH is illustrated in a quadrangular shape, e.g., rectangular shape in FIG. 1, the shape of the deposition hole DH may be appropriately changed according to a pattern shape of an emission layer. In an embodiment, the shape of the deposition hole DH may be changed to a circular shape, an elliptical shape, or the like, for example.

A plurality of deposition masks 100 may be coupled or fixed to the frame 50. The frame 50 may define an opening 60 exposing the deposition masks 100. The deposition mask 100 may cross the opening and may be disposed on the frame 50. A plurality of deposition masks 100 may be repeatedly arranged on the frame 50 so as not to overlap each other along the first direction.

In an embodiment, both end portions of the deposition mask 100 in the second direction may be welded and fixed to the frame 50.

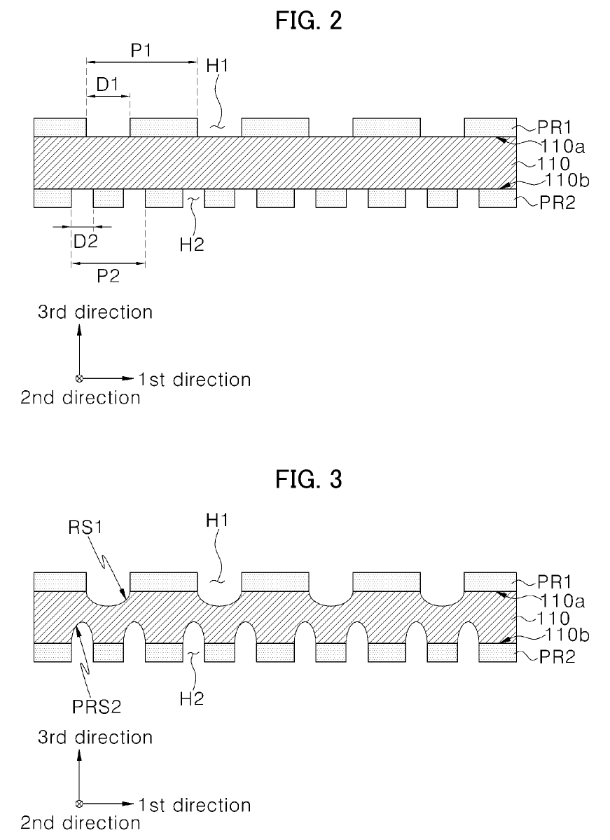

FIGS. 2-7 are schematic cross-sectional views illustrating embodiments of a method of manufacturing a deposition mask.

Referring to FIG. 2, a first photoresist pattern PR1 and a second photoresist pattern PR2 may be formed on a first surface 110a and a second surface 110b of the mask body 110, respectively.

The mask body 110 may include a material having a heat resistance and being stable in a thermal deposition or a vapor deposition, so that a thermal deformation may be suppressed. In an embodiment, the mask body 110 may include stainless steel (“SUS”), an Invar alloy, nickel (Ni), cobalt, a nickel-cobalt alloy, or the like, for example. In an embodiment, the mask body 110 may include the Invar alloy.

The first surface 110a and the second surface 110b of the mask body 110 may oppose each other, and may correspond to a top surface and a bottom surfaces of the mask body 110, respectively. In an embodiment, the second surface 110b may be a deposition source injection surface through which a deposition source is introduced into the deposition mask 100. The first surface 110a may be a deposition source supply surface from which the deposition source passing through the deposition mask 100 is supplied to an object.

In an embodiment, a first photoresist layer and a second photoresist layer may be formed on the first surface 110a and the second surface 110b of the mask body 110, respectively, for example. Each of the first photoresist layer and the second photoresist layer may be partially removed by performing exposure and development processes. Accordingly, the first photoresist pattern PR1 and the second photoresist pattern PR2 including holes may be formed from the first photoresist layer and the second photoresist layer, respectively.

The first photoresist pattern PR1 may include a plurality of first holes H1, and the second photoresist pattern PR2 may include a plurality of second holes H2.

A width (e.g., a width in the first direction) of each of the first holes H1 may be indicated as a first width D1, and a width (e.g., a width in the first direction) of each of the second holes H2 may be indicated as a second width D2. In an embodiment, the first width D1 may be greater than the second width D2.

In an embodiment, an interval between neighboring first holes H1 may be greater than an interval between neighboring second holes H2. In an embodiment, a pitch of the first holes H1 may be represented by a first pitch P1, and a pitch of the second holes H2 may be represented by a second pitch P2, for example. The first pitch P1 may be greater than the second pitch P2.

As described above, the second holes H2 defined in the second photoresist pattern PR2 formed on the second surface 110b of the mask body 110 may have a width and/or a pitch smaller than that of the first holes H1 defined in the first photoresist pattern PR1 formed on the first surface 110a of the mask body 110.

In an embodiment, the number of the second holes H2 may be greater than the number of the first holes H1.

Referring to FIG. 3, a first etching may be performed through each of the first and second surfaces 110a and 110b of the mask body 110 using the photoresist patterns PR1 and PR2 as etching masks.

In an embodiment, an etching gas or an etchant solution may be sprayed into each of the first and second surfaces 110a and 110b of the mask body 110 through the first and second holes H1 and H2. The etching gas or the etchant solution may have an etching selectivity for the mask body 110 including the Invar alloy, and may include, e.g., ferric chloride (FeCl3).

A first recess RS1 may be defined at an upper portion of the mask body 110, and a second preliminary recess PRS2 may be defined at a lower portion of the mask body 110 by the first etching. The first recess RS1 may have a concave portion shape recessed from the first surface 110a of the mask body 110, and the second preliminary recess PRS2 may have a concave portion shape recessed from the second surface 110b of the mask body 110.

The first recess RS1 and the second preliminary recess PRS2 may be separated or spaced apart from each other without meeting each other in the mask body 110.

A width and/or an interval of the first recesses RS1 may be greater than a width and/or an interval of the second preliminary recess PRS2 according to the size and the interval of the first and second holes H1 and H2 as described above.

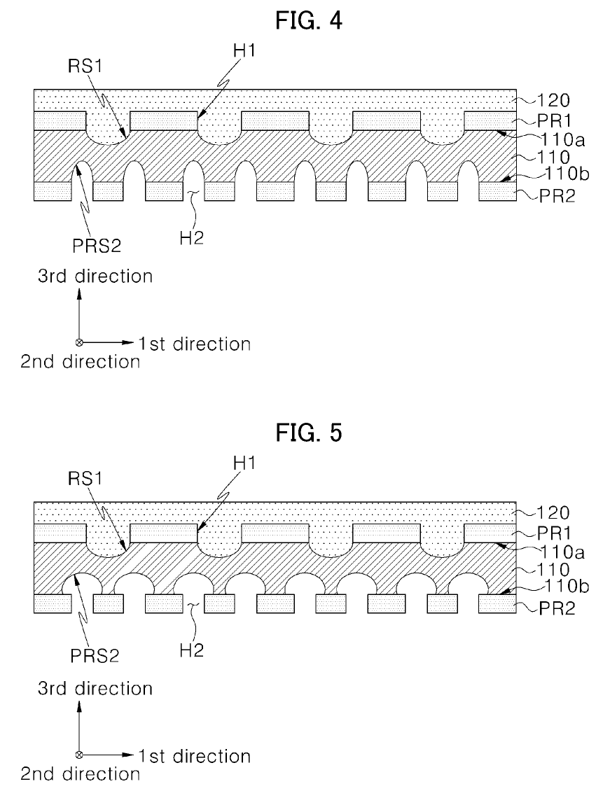

Referring to FIG. 4, a blocking layer 120 covering the first photoresist pattern PR1 may be formed on the first surface 110a of the mask body 110. The blocking layer 120 may fill the first recesses RS1 and cover the first photoresist pattern PR1.

The blocking layer 120 may include or consist of an organic polymer layer such as an epoxy resin, an acrylic resin, an ester resin, or the like. The blocking layer 120 may prevent the etching gas or the etchant solution from being leaked through the first recess RS1 during a second etching described later.

Referring to FIG. 5, the second etching process may be performed through the second surface 110b of the mask body 110. The second etching may be performed using the same etching gas or etchant solution as that used in the first etching.

The second etching may be selectively performed in a direction of the second surface 110b, and the etching gas or the etchant solution may be injected through the second holes H2 defined in the second photoresist pattern PR2.

The second preliminary recess PRS2 may be expanded in a direction toward the first surface 110a by the second etching.

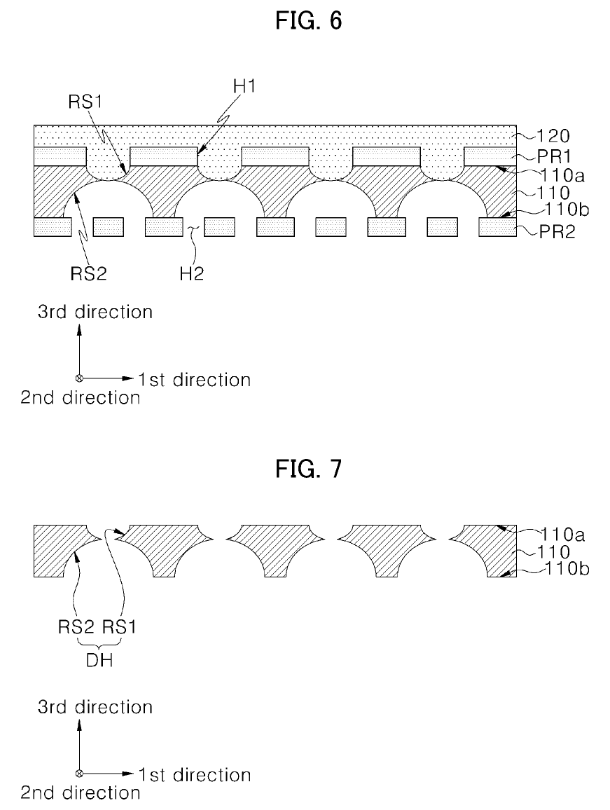

Referring to FIG. 6, the second preliminary recess PRS2 may be expanded by the second etching to be merged with the first recess RS1.

In an embodiment, a pair of the second preliminary recesses PRS2 next (adjacent) to each other in the first direction may be merged into one second recess RS2 through the second etching. The one second recess RS2 in which the pair of the second preliminary recesses PRS2 are merged may be connected to or merged with one first recess RS1.

Referring to FIG. 7, the blocking layer 120, and the first and second photoresist patterns PR1 and PR2 may be removed. In an embodiment, the blocking layer 120, and the first and second photoresist patterns PR1 and PR2 may be removed through an ashing process and/or a strip process, for example.

Accordingly, the first recess RS1 and the second recess RS2 may be connected to each other to form the deposition hole DH.

The second recess RS2 may be provided as a deposition source inlet, and the first recess RS1 may be provided as a deposition source outlet. The second recess RS2 may have a width or a volume larger than that of the first recess RS1. Accordingly, the deposition source may be easily introduced through the second recess RS2, and the deposition source may be discharged or injected according to a size of a fine pattern through the first recess RS1.

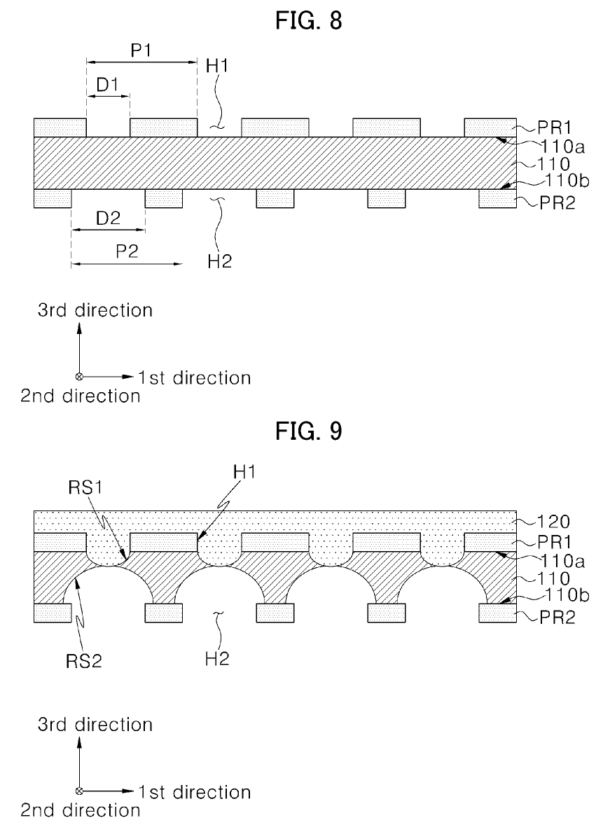

FIGS. 8 and 9 are schematic cross-sectional views illustrating a method of manufacturing a deposition mask according to a comparative example.

Referring to FIG. 8, the width D2 of the second hole H2 of the second photoresist pattern PR2 may be increased to be greater than the width of the first hole H1 to define the second recess RS2 having a finally relatively large size, and the pitch P2 of the second hole H2 may also be relatively increased. Accordingly, one second hole H2 may correspond to one first hole H1.

Referring to FIG. 9, as described with reference to FIGS. 3-6, the first etching and the second etching may be performed. According to the comparative example, the etchings may be performed such that one second recess RS2 is connected to one first recess RS1 through the second hole H2.

According to the above-described comparative example, the second recess RS2 is directly defined through the one second hole H2, and an etching amount for defining the second recess RS2 may be excessively increased. Accordingly, a sufficient thickness of the mask body 110 is desired to separately form the desired deposition hole DH. Accordingly, formation of the deposition mask in the form of a thin film, which is desired for a fine pattern deposition, may not be stably implemented.

However, according to the above-described embodiments, the width of the second holes H2 defined in the second surface 110b may be reduced, so that two second holes H2 may correspond to one first hole H1.

Thus, an etching amount for defining the second recess RS2 may be divided and dispersed into two second preliminary recesses PRS2. Therefore, even when the thickness of the mask body 110 is reduced, the deposition holes DH having relatively high resolution/fine pitch may be stably formed.

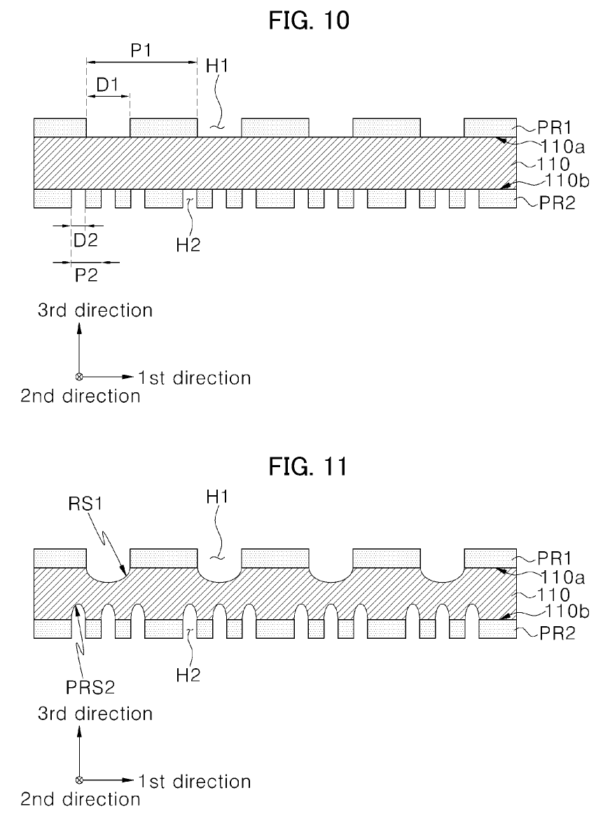

FIGS. 10-14 are schematic cross-sectional views illustrating embodiments of a method of fabricating a deposition mask. Detailed descriptions on processes and materials substantially the same as or similar to those described with reference to FIGS. 2-7 are omitted.

In an embodiment, three or more second holes H2 or second preliminary recesses PRS2 may correspond to one first hole H1 or first recess RS1.

Referring to FIG. 10, as described with reference to FIG. 2, the second photoresist pattern PR2 having the second holes H2 of the second width D2 and the second pitch P2 may be formed on the second surface 110b of the mask body 110. The first photoresist pattern PR1 having the first holes H1 of the first width D1 and the first pitch P1 may be formed on the first surface 110a of the mask body 110.

In the embodiment of FIG. 10, the second width D2 and the second pitch P2 may be reduced compared to that in the embodiment of FIG. 2. In an embodiment, the second width D2 and the second pitch P2 may be adjusted so that three second holes H2 correspond to one first hole H1.

Referring to FIG. 11, a process substantially the same as or similar to that described with reference to FIG. 3 may be performed. In an embodiment, the first recesses RS1 indented from the first surface 110a of the mask body 110 and the second preliminary recesses PRS2 indented from the second surface 110b of the mask body 110 may be formed by the first etching.

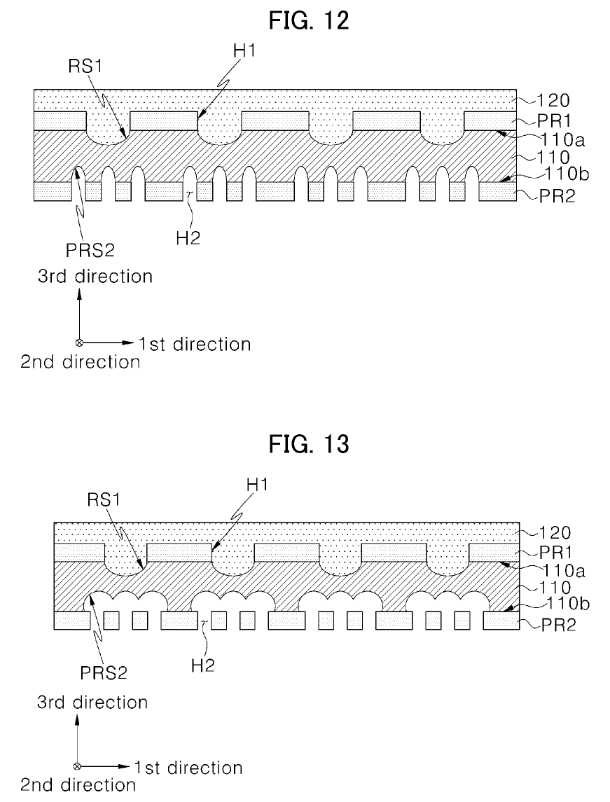

Referring to FIG. 12, a process substantially the same as or similar to that described with reference to FIG. 4 may be performed. In an embodiment, the blocking layer 120 may be formed on the first surface 110a of the mask body 110 to fill the first recesses RS1 and cover the first photoresist pattern PR1.

Referring to FIG. 13, as described with reference to FIG. 5, the second preliminary recesses PRS2 may be expanded by the second etching. Neighboring second preliminary recesses PRS2 may be merged with each other while being expanded. In an embodiment, three second preliminary recesses PRS2 may be merged with each other.

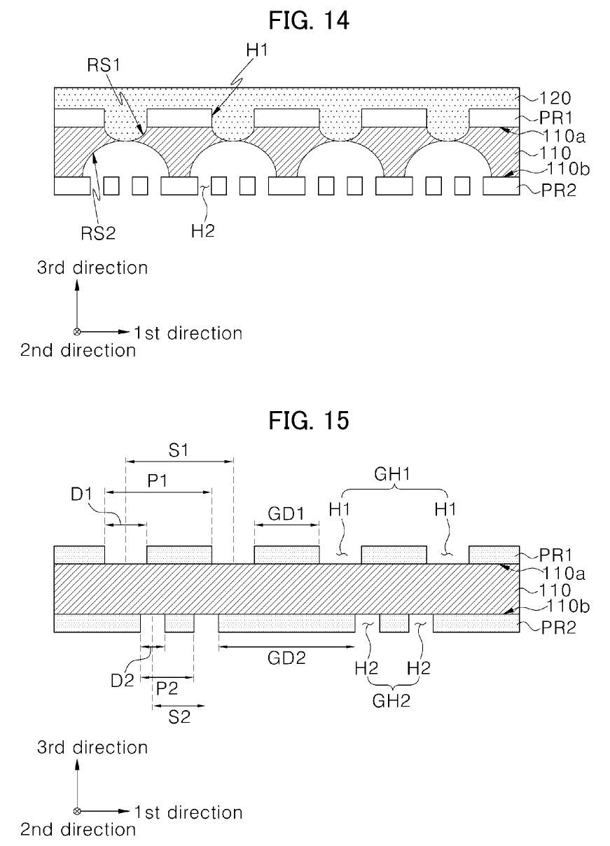

Referring to FIG. 14, during the second etching, three second preliminary recesses PRS2 may be merged to define substantially one second recess RS2. The second recess RS2 may have a width or a volume greater than that of the first recess RS1, and may be merged with the first recess RS1.

Thereafter, as described with reference to FIG. 7, the blocking layer 120 and the photoresist patterns PR1 and PR2 may be removed. Accordingly, the deposition hole DH in which the first recess RS1 and the second recess RS2 are integrally connected may be defined.

In an embodiment, the width D2 and the pitch P2 of the second holes H2 may be adjusted such that four or more second holes H2 (or the second preliminary recesses PRS2) correspond to one first hole H1 (or the first recess RS1).

FIGS. 15-19 are schematic cross-sectional views illustrating embodiments of a method of fabricating a deposition mask. Detailed descriptions on processes and materials substantially the same as or similar to those described with reference to FIGS. 2-7 are omitted.

Referring to FIG. 15, as described with reference to FIG. 2, the first photoresist pattern PR1 defining the first holes H1 may be formed on the first surface 110a of the mask body 110. The second photoresist pattern PR2 defining the second holes H2 may be formed on the second surface 110b of the mask body 110. As described above, the second width D2 of the second hole H2 may be less than the first width D1 of the first hole H1.

In an embodiment, a first hole group GH1 including two neighboring first holes H1 may be defined. A plurality of first hole groups GH1 may be arranged along the first direction. An interval between neighboring first hole groups GH1 may be indicated as a first interval GD1.

In an embodiment, a second hole group GH2 including two neighboring second holes H2 may be defined. A plurality of second hole groups GH2 may be arranged along the first direction. An interval between neighboring second hole groups GH2 may be indicated as a second interval GD2.

In an embodiment, a width of the second hole group GH2 may be less than a width of the first hole group GH1. In an embodiment, a distance between the second hole groups GH2 (the second interval GD2) may be greater than a distance between the first hole groups GH1 (the first interval GD1).

In an embodiment, a pitch (a second pitch P2) of the second hole H2 in the second hole group GH2 may be less than a pitch (a first pitch P1) of the first hole H1 in the first hole group GH1. Accordingly, an interval (a second hole interval S2) of the second holes H2 in the second hole group GH2 may be less than an interval (a first hole interval S1) of the first holes H1 in the first hole group GH1.

In FIG. 15, the hole intervals S1 and S2 may be distances between centers of neighboring (adjacent) holes included in the hole group.

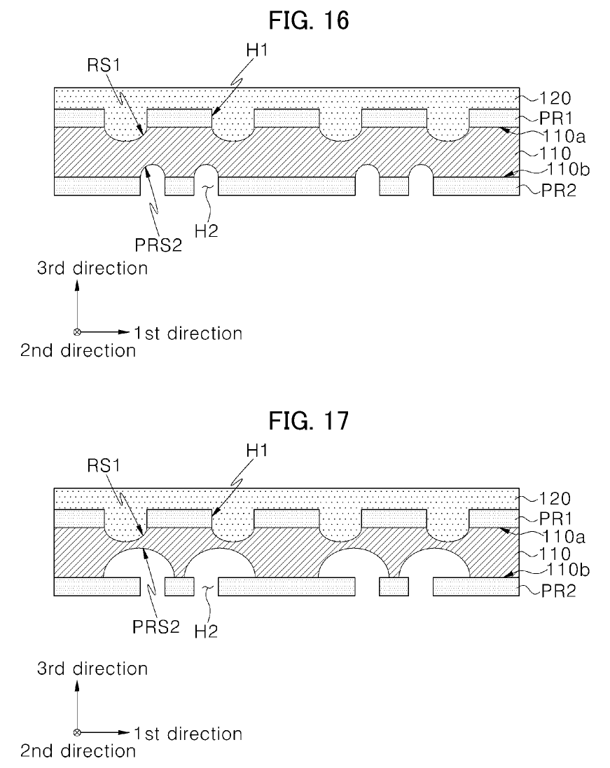

Referring to FIG. 16, a process substantially the same as or similar to the process described with reference to FIGS. 3 and 4 may be performed. In an embodiment, the first etching may be performed to define the first recesses RS1 through the first holes H1, and the second preliminary recesses PRS2 may be defined through the second holes H2.

Thereafter, the blocking layer 120 covering the first photoresist pattern PR1 may be formed to fill the first recesses RS1.

Referring to FIG. 17, as described with reference to FIG. 5, the second preliminary recesses PRS2 may be expanded toward the first surface 110a by the second etching through the second holes H2.

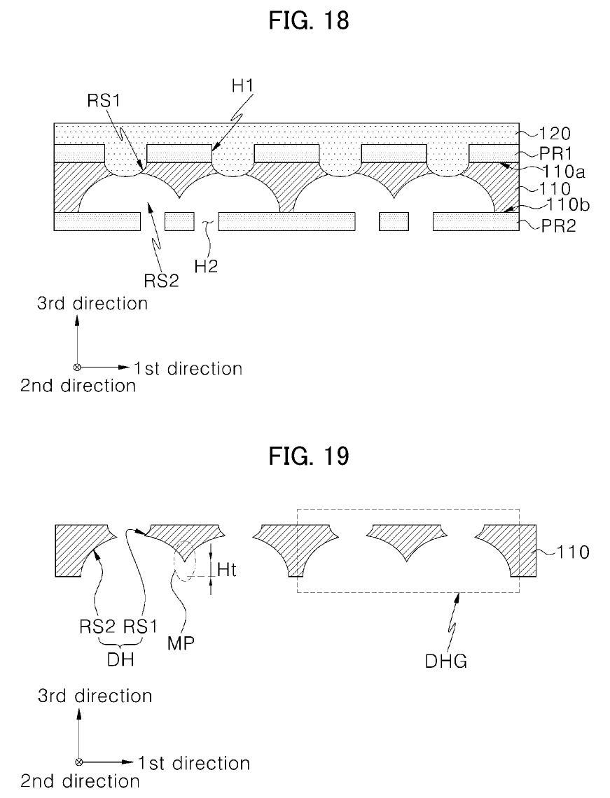

Referring to FIG. 18, as described with reference to FIG. 6, the second preliminary recesses PRS2 may be additionally expanded by continuing the second etching to define the second recess RS2. The second recess RS2 may be merged or connected with the first recess RS1 by the second etching.

In an embodiment, side portions of the neighboring second recesses RS2 formed through the second hole group GH2 may be merged with each other.

Referring to FIG. 19, as described with reference to FIG. 7, the blocking layer 120 and the photoresist patterns PR1 and PR2 may be removed. Accordingly, the deposition mask 100 defining the deposition hole DH defined by connecting the first recess RS1 and the second recess RS2 to each other may be formed.

As described above, side portions of the neighboring (adjacent) second recesses RS2 formed by the second hole group GH2 may be merged with each other. Thus, while one second recess RS2 corresponds to one first recess RS1, facing side portions of a pair of neighboring (adjacent) second recesses RS2 may be merged with each other.

In an embodiment, a deposition hole group DHG may be defined by the second recesses RS2 merged with each other and the first recesses RS1 connected to the second recesses RS2, for example. The deposition mask 100 may define a plurality of deposition hole groups DHG.

The deposition hole group DHG may include a merged portion MP at which the side portions of neighboring (adjacent) second recesses RS2 are merged with each other. A height Ht of the merged portion MP from the second surface 110b may be less than a maximum height of the second recess RS2 from the second surface 110b.

According to the above-described embodiments, the width of the second recess RS2 may be increased while forming the merged portion MP by reducing the width and the interval of the second holes H2 defined in the second hole group GH2. Accordingly, etching stability for defining the second recess RS2 may be improved while maintaining 1:1 matching between the first recess RS1 and the second recess RS2.

In FIGS. 15-19, the embodiment in which two first recesses RS1 and two merged recesses RS2 are included in the deposition hole group DHG is illustrated, but the number of the first recesses RS1 and the second recesses RS2 included in the deposition hole group DHG may be increased to three or more.

In an embodiment, the first hole group GH1 may include three first holes H1, and the second hole group GH2 may include three second holes H2, for example. In this case, the deposition hole group DHG may include three first recesses RS1, and may include three second recesses RS2 corresponding to each of the first recesses. The three second recesses RS2 may be merged with each other by two merged portions MP.

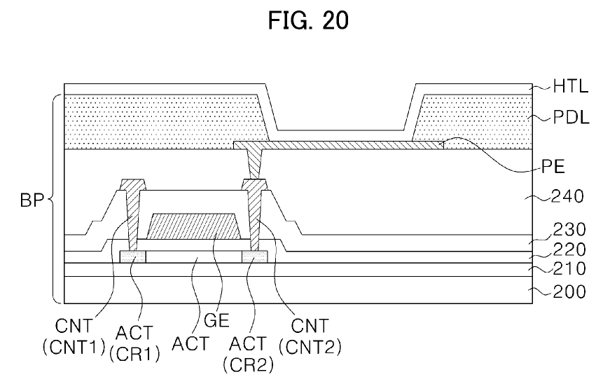

FIGS. 20-25 are schematic diagrams illustrating embodiments of a method of manufacturing a display device.

Referring to FIG. 20, a back-plane structure BP including a base substrate 200, and a transistor and a pixel electrode PE formed on the base substrate 200 may be prepared.

The base substrate 200 may be provided as a back-plane substrate of a display device. A glass substrate or a plastic substrate may be used as the base substrate 200. In an embodiment, the base substrate 200 may include a polymer material having transparency and flexibility. In this case, the base substrate 200 may be used in a transparent flexible display device.

In an embodiment, the base substrate 200 may include a polymer material such as polyimide, polysiloxane, an epoxy resin, an acrylic resin, polyester, or the like, for example. In an embodiment, the base substrate 200 may include polyimide.

A buffer layer 210 may be formed on a top surface of the base substrate 200. Moisture penetrating through the base substrate 200 may be blocked by the buffer layer 210, and diffusion of impurities between structures formed on the base substrate 200 and the base substrate 200 may also be blocked by the buffer layer 210. The buffer layer 210 may cover an entirety of the top surface of the base substrate 200.

The buffer layer 210 may include, e.g., an inorganic insulating material such as silicon oxide, silicon nitride, and/or silicon oxynitride. These may be used alone or in any combinations thereof. In an embodiment, the buffer layer 210 may have a stacked structure including a silicon oxide layer and a silicon nitride layer.

The buffer layer 210 may be formed by a deposition process such as a chemical vapor deposition (“CVD”) process, a sputtering process, and an atomic layer deposition (“ALD”) process to include the inorganic insulating material.

In an embodiment, the buffer layer 210 may include an organic layer, and may have a multi-layered structure of an organic layer and an inorganic layer.

A semiconductor layer may be formed on a top surface of the buffer layer 210 by a deposition process such as a sputtering process. The semiconductor layer may be patterned to be repeatedly/regularly arranged for each pixel by a photo-lithography process, so that an active layer ACT may be formed from the semiconductor layer.

In an embodiment, the semiconductor layer may be formed to include a silicon compound such as polysilicon or amorphous silicon. In an embodiment, the semiconductor layer may be formed to include an oxide semiconductor such as indium gallium zinc oxide (“IGZO”), zinc tin oxide (“ZTO”), or indium tin zinc oxide (“ITZO”).

A gate insulation layer 220 covering the active layer ACT may be formed on the buffer layer 210. A gate electrode GE may be formed on the gate insulation layer 220.

The gate insulation layer 220 may be formed using the inorganic insulating material and the deposition process as described above.

A first conductive layer may be formed on a top surface of the gate insulation layer 220 by the above-described deposition process, and the first conductive layer may be partially etched by a photo-lithography process to form the gate electrode GE

In an embodiment, the first conductive layer may include a metal such as Ag, Mg, Al, W, Cu, Ni, Cr, Mo, Ti, Pt, Ta, Nd, Sc, etc., any alloys thereof, or a nitride thereof, for example. In an embodiment, the first conductive layer may be formed in a multi-layered structure (e.g., a Ti layer, an Al layer and a Ti layer).

Thereafter, a p-type dopant or an n-type dopant may be injected into the active layer ACT by an ion implantation process using the gate electrode GE as an ion implantation mask. Accordingly, a first contact region CR1 and a second contact region CR2 may be formed at one side and an opposite side of the active layer ACT, respectively. The first contact region CR1 and the second contact region CR2 may correspond to a source region and a drain region, respectively.

A portion of the active layer ACT between the first contact region CR1 and the second contact region CR2 overlapping the gate electrode GE in a vertical direction may be defined as a channel region.

A transistor may be defined by the active layer ACT including the channel region, the first contact region CR1 and the second contact region CR2, the gate insulation layer 220, and the gate electrode GE. The transistor may be provided as a thin film transistor (“TFT”) of a display device, and may serve as a pixel driving transistor or a switching transistor.

An insulating interlayer 230 covering the gate insulation layer 220 and the gate electrode GE may be formed on the active layer ACT. A contact electrode CNT that may be in contact with or electrically connected to the active layer ACT may be formed on the insulating interlayer 230.

The insulating interlayer 230 may be formed by the above-described deposition process to include an inorganic insulating material such as silicon oxide, silicon nitride, silicon oxynitride, or the like. The insulating interlayer 230 may be formed in a single-layered structure or a multi-layered structure including different materials from each other.

In an embodiment, the gate insulation layer 220 may be formed in a pattern covering the channel region by an etching process using the gate electrode GE as an etching mask. When the active layer ACT includes an oxide semiconductor, hydrogen (H) included in the insulating interlayer 230 may be diffused or transferred to the active layer ACT. Accordingly, a carrier concentration may be increased by hydrogen to form the contact regions CR1 and CR2 at the side portions of the active layer ACT.

The contact electrode CNT may extend through the insulating interlayer 230, and may be in contact with or connected to the active layer ACT. The contact electrode CNT may also extend through the gate insulation layer 220.

The contact electrode CNT may include a first contact electrode CNT1 connected to or in contact with the first contact region CR1 of the active layer ACT, and a second contact electrode CNT2 connected to or in contact with the second contact region CR2 of the active layer ACT. The first contact electrode CNT1 and the second contact electrode CNT2 may serve as a source electrode and a drain electrode, respectively.

Contact holes may be defined by partially etching the insulating interlayer 230. In an embodiment, contact holes exposing the first contact region CR1 and the second contact region CR2, respectively, may be defined, for example. A second conductive layer filling the contact holes may be formed on the insulating interlayer 230, and the second conductive layer may be partially etched to form the first contact electrode CNT1 and the second contact electrode CNT2.

The second conductive layer may include a metal or an alloy substantially the same as or similar to that of the first conductive layer, and may be formed by the above-described deposition process such as a sputtering process.

A planarization layer 240 covering the contact electrode CNT may be formed on the insulating interlayer 230. The planarization layer 240 may accommodate a via portion electrically connecting the pixel electrode PE to the second contact electrode CNT2.

In an embodiment, the planarization layer 240 may include an organic material such as polyimide, an epoxy resin, an acrylic resin, polyester, a siloxane resin, benzocyclobutene (“BCB”), or the like. In an embodiment, the planarization layer 240 may be formed by a coating process such as a spin coating process, for example.

The pixel electrode PE may be formed in each pixel to be electrically connected to the transistor. The pixel electrode PE may be formed on the planarization layer 240 and may be electrically connected to, e.g., the second contact electrode CNT2.

In an embodiment, the planarization layer 240 may be partially etched to define a via hole exposing a top surface of the second contact electrode CNT2, for example. A conductive layer filling the via hole and including a metal material or a transparent conductive oxide may be formed on a top surface of the planarization layer 240, and the conductive layer may be etched to form the pixel electrode PE. The pixel electrode PE may include the via portion filling the via hole.

The pixel electrode PE may be provided as an anode and may include a relatively high work function conductive material that may promote hole injection. The pixel electrode PE may be formed as a transmissive electrode. The pixel electrode 180 may include a transparent conductive oxide such as indium tin oxide (“ITO”), indium zinc oxide (“IZO”), zinc oxide (ZnO), and indium tin zinc oxide (“ITZO”).

The pixel electrode PE may be formed as a translucent electrode or a reflective electrode. The pixel electrode PE may include a metal selected from Ag, Mg, Cu, Al, Pt, Pd, Au, Ni, Nd, Ir, Cr, Li, Ca, Li, Mo, Ti, W, In, Sn and Zn, or an alloy or a compound (e.g., LiF) including at least one therefrom.

The pixel electrode PE may have a single-layered structure or a multi-layered structure. In an embodiment, the pixel electrode PE may have a triple-layered structure of ITO/Ag/ITO, for example.

A pixel defining layer PDL exposing a top surface of the pixel electrode PE may be formed on the planarization layer 240. The pixel defining layer PDL may cover a peripheral portion of the pixel electrode PE. In an embodiment, a pixel region or a light-emitting region may be defined by a sidewall of the pixel defining layer PDL, for example.

The pixel defining layer PDL may include, e.g.., an organic material such as a polysiloxane resin, a polyimide resin, an acrylic resin, or the like. The pixel defining layer PDL may include a colorant material such as a black pigment/dye dispersed in a resin material.

In an embodiment, a hole transport layer HTL may be formed on the back-plane structure BP manufactured as described above. The hole transport layer HTL may be formed as a common layer continuously formed in a plurality of pixels.

In an embodiment, the hole transport layer HTL may include a hole transporting material such as 4,4',4"-[tris(3-methylphenyl)phenylamino] triphenylamine (“m-MTDATA”), 4,4'4"-tris(N,N-diphenylamino)triphenylamine (“TDATA”), 4,4',4"-tris[N(2-naphthyl)-N-phenylamino]-triphenylamine (“2-TNATA”), N,N'-di(naphthalene-l-yl)-N,N'-diphenyl-benzidine (“NPB”), N,N'-bis(3-methylphenyl)-N,N'-diphenyl-[1,1'-biphenyl]-4,4'-diamine (“TPD”), 4,4',4"-tris(N-carbazolyl)triphenylamine (“TCTA”), poly(3,4-ethylenedioxythiophene)/poly(4-styrenesulfonate) (“PEDOT/PSS”), or the like, for example.

The hole transport layer HTL may be formed by a process such as a thermal deposition, a vapor deposition, a vacuum deposition, a spin coating, an inkjet printing, a laser printing, a casting, a laser thermal transfer, or the like.

In an embodiment, a hole injection layer may be further formed between the pixel electrode PE and the hole transport layer HTL.

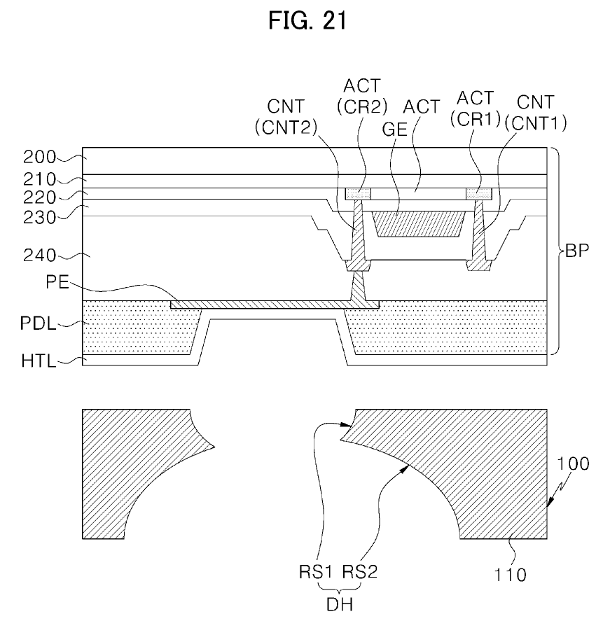

Referring to FIG. 21, the back-plane structure BP may be disposed on the deposition mask 100 according to the above-described embodiments.

In an embodiment, the back-plane structure BP may be aligned such that the pixel electrode PE of the back-plane structure BP may face the deposition hole DH of the deposition mask 100. The back-plane structure BP and the deposition mask 100 may be aligned with each other such that the first recess RS1 of the deposition hole DH may face the pixel electrode PE.

As described above, the hole transport layer HTL may be formed on the pixel electrode PE. Accordingly, the back-plane structure BP and the deposition mask 100 may be aligned with each other such that the pixel electrode PE may face the first recess RS1 of the deposition mask 100 with the hole transport layer HTL interposed therebetween.

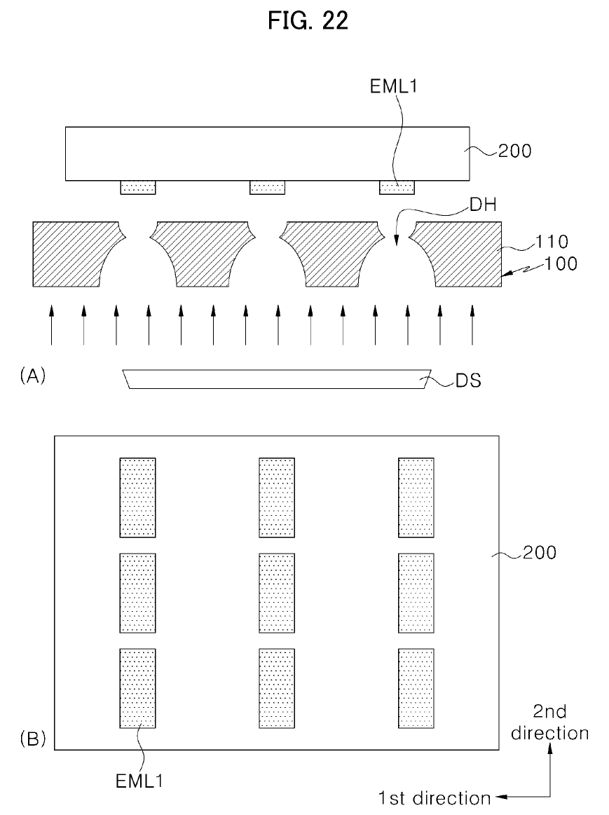

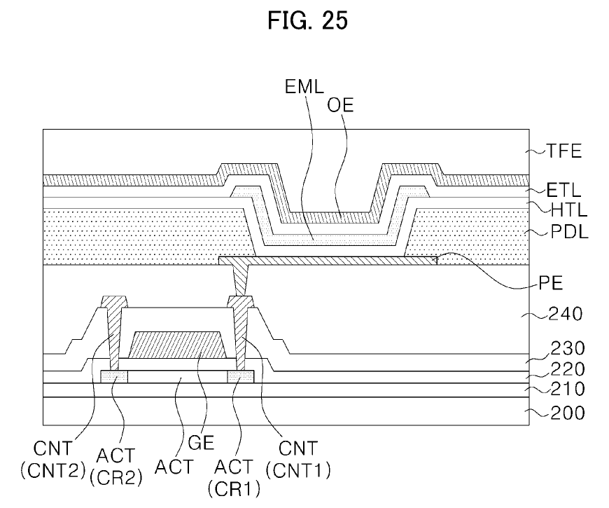

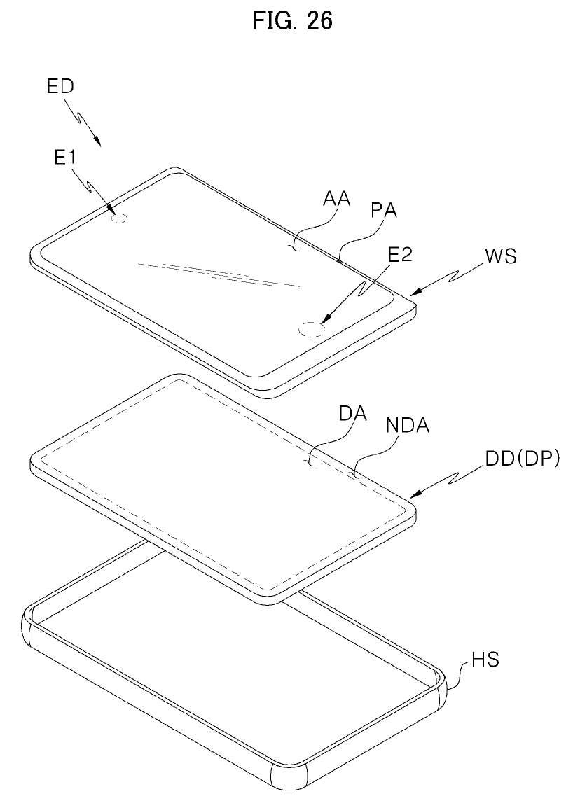

Thereafter, as illustrated in FIGS. 22-24, an emission layer EML (refer to FIG. 25) may be formed on the pixel electrode PE by a deposition process using the deposition mask 100. Portions (A) of FIGS. 22-24 are cross-sectional views schematically illustrating a deposition process, and portions (B) of FIGS. 22-24 are plan views illustrating an arrangement in which the emission layers EML are formed.

For convenience of description, detailed illustration of elements of the back-plane structure BP excepting for the base substrate 200 in FIGS. 22-24 are omitted.

In an embodiment, a first emission layer EML1 using a first emission material that emits a first color, a second emission layer EML2 using a second emission material that emits a second color, and a third emission layer EML3 using a third emission material that emits a third color may be sequentially formed while shifting the deposition mask 100. The first to third colors may be different colors.

Referring to FIG. 22, the first emission material included in the first emission layer EML1 may be deposited using the deposition mask 100 through a deposition source DS. Accordingly, the first emission layers EML1 may be formed on the pixel electrodes PE corresponding to the first pixel.

In an embodiment, an organic light-emitting material corresponding to the first emission material may be supplied from the deposition source DS by a thermal evaporation deposition. In an embodiment, the organic light-emitting material may include a host material excited by holes and electrons, and a dopant material that increases luminous efficiency through absorption and release of energy, for example.

The organic light-emitting material may be vaporized and injected into the second recess RS2 of the deposition mask 100, and sprayed from the first recess RS1 onto the pixel electrode PE.

As illustrated in (B) of FIG. 22, a plurality of first emission layers EML1 may be formed along the second direction to form a first emission layer column. A plurality of first emission layer columns may be formed along the first direction.

In an embodiment, the first emission layer EML1 may correspond to a blue emission layer.

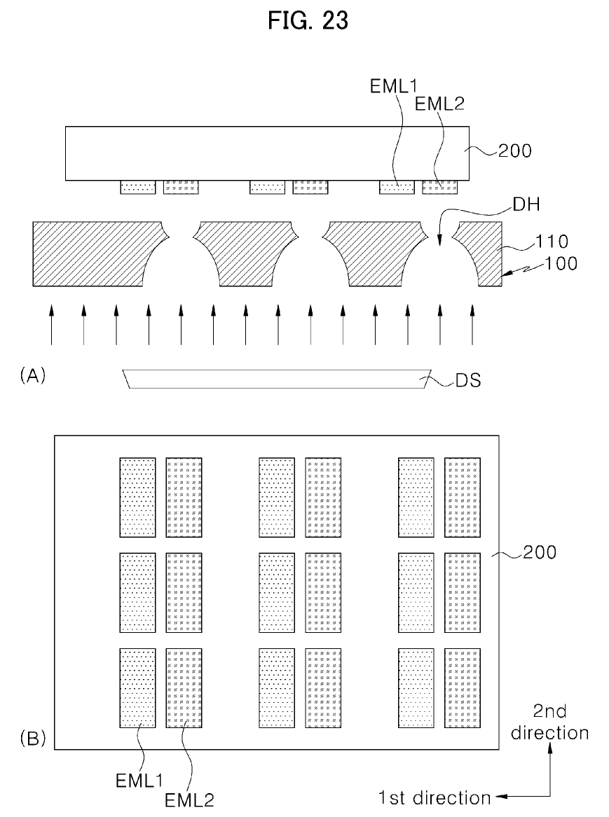

Referring to FIG. 23, the deposition holes DH may be aligned with the pixel electrodes PE corresponding to the second pixel by shifting the deposition mask 100.

Thereafter, the second emission material included in the second emission layer EML2 may be deposited using the deposition mask 100 through the deposition source DS.

As illustrated in (B) of FIG. 23, a plurality of second emission layers EML2 may be formed along the second direction to form a second emission layer column. A plurality of second emission layer columns may be formed along the first direction. In an embodiment, the second emission layer column may be formed between the first emission layer columns, for example.

In an embodiment, the second emission layer EML2 may correspond to a red emission layer.

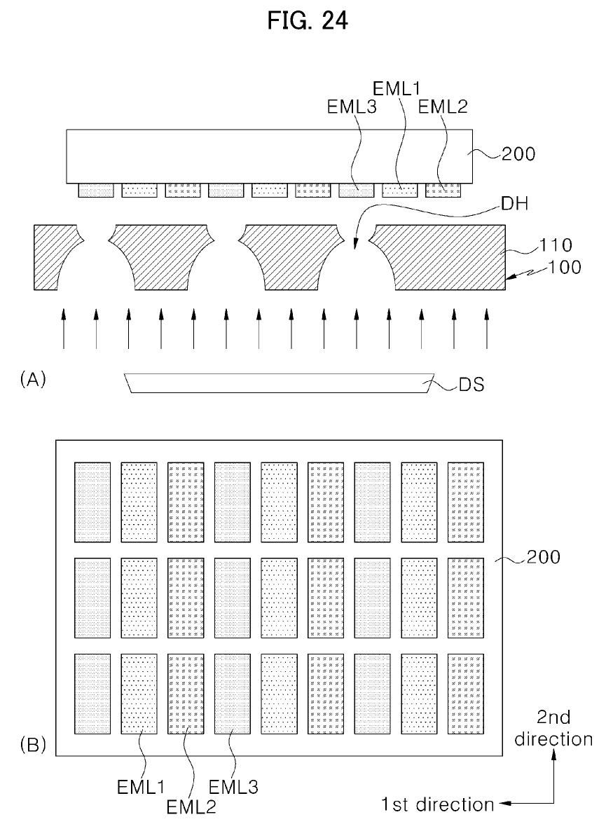

Referring to FIG. 24, the deposition holes DH may be aligned with the pixel electrodes PE corresponding to the third pixel by shifting the deposition mask 100.

Thereafter, the third emission material included in the third emission layer EML3 may be deposited by the deposition mask 100 through the deposition source DS.

As illustrated in (B) of FIG. 24, a plurality of third emission layers EML3 may be formed in the second direction to form a third emission layer column. A plurality of third emission layer columns may be formed along the first direction. In an embodiment, the third emission layer column may be formed between the first emission layer column and the second emission layer column next (adjacent) to each other, for example.

In an embodiment, the third emission layer EML3 may correspond to a green emission layer.

Referring to FIG. 25, an electron transport layer ETL may be formed on the pixel defining layer PDL (or the hole transport layer HTL) and the emission layer EML formed as described with reference to FIGS. 22-24. In an embodiment, the electron transport layer ETL may be formed as a common layer continuously provided in the first to third pixels.

The electron transport layer ETL may include an electron transport material such as an anthracene compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

The electron transport layer ETL may be formed by a process such as a thermal deposition, a vapor deposition, a vacuum deposition, a spin coating, an inkjet printing, a laser printing, a casting, a laser thermal transfer, or the like.

A counter electrode OE may be formed on the pixel defining layer PDL and the emission layer EML. The counter electrode OE may be formed on the electron transport layer ETL. In an embodiment, an electron injection layer may be further formed between the counter electrode OE and the electron transport layer ETL.

The counter electrode OE may be formed as a common electrode that may be continuously provided commonly in the first to third pixels.

The counter electrode OE may be provided as an electron injection electrode or a cathode. The counter electrode OE may include a metal, an alloy, an electrically conductive compound, or the like, having a relatively low work function.

In an embodiment, the counter electrode OE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like, for example. These may be used alone or in a combination of two or more therefrom.

The counter electrode OE may be formed as a transmissive electrode, a translucent electrode, or a reflective electrode. The counter electrode OE may have a single-layered structure or a multi-layered structure.

An encapsulation layer TFE may be formed on the counter electrode OE. The encapsulation layer TFE may protect the emission layers EML from moisture or oxygen.

The encapsulation layer TFE may include may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (“AGE”)), or any combination thereof; or a combination of the inorganic and organic layers.

The encapsulation layer TFE may be formed in a single-layered structure or a multi-layered structure. In an embodiment, the encapsulation layer TFE may have a sequential stacked structure of a first inorganic layer, an organic layer and a second inorganic layer.

In an embodiment, an optical functional layer or a sensor functional layer such as a color filter, a polarizing plate, a touch sensor layer, or the like, may be additionally formed on the encapsulation layer TFE.

The emission layers EML of relatively high resolution and fine pitch may be formed using the deposition mask 100 fabricated. In an embodiment, the display device may be manufactured as an organic light-emitting diode (“OLED”) display device with relatively high resolution of 500 pixels per inch (ppi) or higher, or 1,000 ppi or higher.

FIG. 26 is an exploded perspective view illustrating embodiments of an electronic device.

In an embodiment, the electronic device may be implemented in the form of a mobile phone (smart phone), a tablet, a personal computer (“PC”), or the like, including a display device that may include an emission layer formed using the above-described deposition mask 100.

Referring to FIG. 26, the electronic device ED may include a window structure WS, the display device DD, and a housing HS. The housing HS, the display device DD, and the window structure WS may be sequentially stacked along the third direction.

The window structure WS may provide an external display surface recognized by a user, such as a viewing surface of an electronic device, e.g., a mobile phone, and may include a transparent material film. In an embodiment, the window structure WS may include glass (e.g., ultra-thin glass (“UTG”)), a hard coating film, a plastic film, or the like, for example.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area or a black matrix area of the electronic device.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In an embodiment, functional device areas E1 and E2 may be included in the active area AA of the window structure WS. In an embodiment, a first functional device area E1 may be included at one end portion of the active area AA and may be implemented, e.g., in the form of a camera hole, for example. The second functional device area E2 may serve as a fingerprint sensing area.

In an embodiment, a sensor structure for a touch sensing or a fingerprint sensing may be disposed in the display panel DP or between the window structure WS and the display panel DP, for example.

The housing HS may serve as a frame structure or a rear housing of the display device DD or the electronic device ED. A cover panel may be disposed between the housing HS and the display panel DP. The housing HS or the cover panel may include a plate (e.g., an SUS plate) supporting the display panel DP. The housing HS or the cover panel may include an elastic body for absorbing shock of the display panel DP.

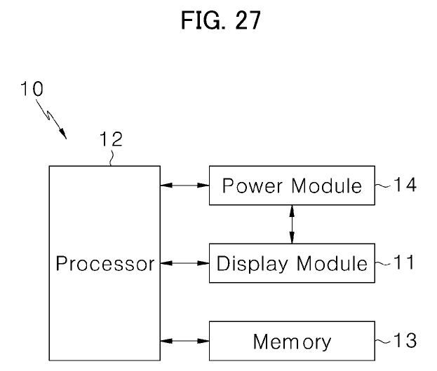

FIG. 27 is a block diagram of an embodiment of an electronic device.

Referring to FIG. 27, an electronic device 10 in an embodiment may include a display module 11, a processor 12, a memory 13 and a power module 14.

The processor 12 may include a central processing unit (“CPU”), an application processor (“AP”), a graphic processing unit (“GPU”), a communication processor (“CP”), an image signal processor (“ISP”) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power desired for the operation of the electronic device 10.

At least one of components of the electronic device 10 as described above may be included in the display device according to the above-described embodiments. Additionally, some of individual modules functionally included in one module may be included in the display device, and others may be provided separately from the display device. In an embodiment, the display module 11 may include the display device, and the processor 12, the memory 13 and the power module 14 may be provided in the form of another device in the electronic device 10 different from the display device, for example.

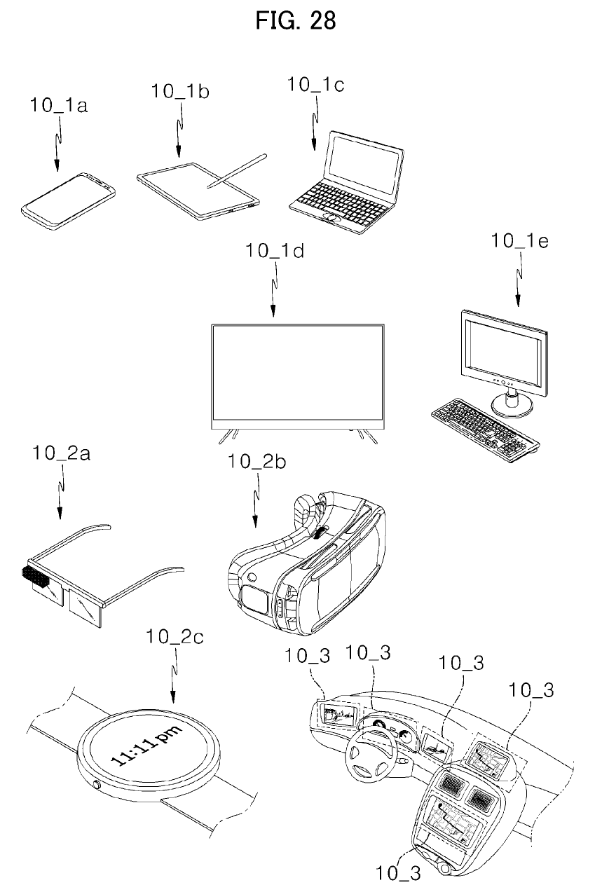

FIG. 28 is a schematic diagram of embodiments of electronic devices.

Referring to FIG. 28, non-limiting embodiments of various electronic devices to which the display device according to the above-described embodiments is applied include an electronic device for displaying an image such as a smartphone 10_1a, a tablet PC 10_1b, a laptop 10_1c, a television (“TV”) 10_1d, a desk monitor 10_1e, or the like; a wearable electronic device including a display module such as smart glasses 10_2a, a head disposed (e.g., mounted) display 10_2b, a smart watch 10_2c, or the like; a vehicle electronic device 10_3 including a display module such as a center information display (“CID”) disposed at a vehicle instrument panel, a center fascia, a dashboard, etc., a head-up display, a room mirror display, or the like. The electronic device may include a virtual reality glass or an augmented reality glass.

What is claimed is:

1. A method of fabricating a deposition mask, the method comprising:
forming a first photoresist pattern including first holes and a second photoresist pattern including second holes on a first surface and a second surface of a mask body, respectively, the first surface and the second surface opposing each other; and
etching the mask body including:
defining first recesses at an upper portion of the mask body through the first holes; and
defining second recesses connected to each of the first recesses at a lower portion of the mask body through the second holes,
wherein each of the second holes has a width smaller than a width of each of the first holes, and each of the second recesses has a width larger than a width of each of the first recesses.

2. The method of claim 1, wherein the first recesses serve as deposition source outlets and the second recesses serve as deposition source inlets.

3. The method of claim 1, wherein a pitch of the second holes is smaller than a pitch of the first holes.

4. The method of claim 1, wherein the number of the second holes is greater than the number of the first holes.

5. The method of claim 1, wherein etching the mask body including the defining the first recesses and the second recesses further comprises:
performing a first etching to define the first recesses at the upper portion of the mask body through the first holes and define a plurality of second preliminary recesses at the lower portion of the mask body through the second holes; and
performing a second etching including:
expanding the plurality of second preliminary recesses and defining the second recesses connected to each of the first recesses.

6. The method of claim 5, wherein the defining the second recesses comprises merging neighboring second preliminary recesses among the plurality of second preliminary recesses to define the second recess connected to one of the first recesses.

7. The method of claim 6, wherein a width of each of the second preliminary recesses is smaller than the width of each of the first recesses.

8. The method of claim 6, wherein the defining the second recesses comprises merging three or more neighboring second preliminary recesses among the plurality of second preliminary recesses to define the second recess.

9. The method of claim 5, further comprising, before performing the second etching, forming a barrier layer filling the first recesses on the first photoresist pattern.

10. The method of claim 9, further comprising, after performing the second etching including the defining the second recesses, removing the barrier layer, the first photoresist pattern and the second photoresist pattern to define a deposition hole through which the first recesses and the second recesses are connected.

11. The method of claim 1, wherein a first hole group is defined by a plurality of neighboring first holes among the first holes, and a second hole group corresponding to the first hole group and including a plurality of neighboring second holes among the second holes is defined.

12. The method of claim 11, wherein an interval between the second holes included in the second hole group is smaller than an interval between the first holes included in the first hole group.

13. The method of claim 11, wherein each of the first hole group and the second hole group is provided in plural so that a plurality of first hole groups are defined in the first surface, and a plurality of second hole groups are defined on the second surface, and
an interval between the first hole groups is smaller than an interval between the second hole groups.

14. The method of claim 11, wherein the etching the mask body further comprises merging facing side portions of the second recesses defined from the second holes included in the second hole group.

15. A method of manufacturing a display device, the method comprising:
preparing a back-plane structure comprising a base substrate, a transistor on the base substrate, and a pixel electrode electrically connected to the transistor;
aligning the back-plane structure over the deposition mask fabricated according to the method of claim 1 such that the pixel electrode faces the first recess of the deposition mask;
forming an emission layer on the pixel electrode by injecting an emission material from the second recess of the deposition mask to the first recess; and
forming a counter electrode on the emission layer.

16. The method of claim 15, wherein forming the emission layer on the pixel electrode comprises:
forming a first emission layer by injecting a first emission material which emits a first color through the deposition mask;
forming a second emission layer by shifting the deposition mask and injecting a second emission material which emits a second color; and
forming a third emission layer by shifting the deposition mask and injecting a third emission material which emits a third color.

17. An electronic device comprising:
the display device manufactured according to the method of claim 15;
a memory; and
a processor executing data included in the memory to control an operation of the display device.

18. A deposition mask comprising:
a mask body; and
deposition holes penetrating the mask body, each of the deposition holes including a first recess and a second recess connected to the first recess, the second recess having a width greater than a width of the first recess, and
wherein facing side portions of the second recesses included in neighboring deposition holes among the plurality of deposition holes are merged with each other

19. The deposition mask of claim 18, wherein the first recess is provided in plural so that a deposition hole group is defined by the second recesses merged with each other through the facing side portions and a plurality of first recesses connected to each of the second recesses.

20. The deposition mask of claim 19, wherein the deposition hole group includes a merged portion at which the second recesses are merged, and
a height of the merged portion is less than a maximum height of each of the second recesses.
